(19) United States
(12) Patent Application Publication
(10) Pub. No.: US 2014/0042615 A1
(43) Pub. Date: Feb. 13, 2014

(54) FLIP-CHIP PACKAGE

(71) Applicant: MediaTek Inc., Hsin-Chu (TW)

(72) Inventors: Ching-Liou HUANG, Qionglin Township (TW); Tung-Hsien HSIEH, Zhubei City (TW); Che-Ya CHOU, Kaohsiung City (TW)

(21) Appl. No.: 13/933,259

(22) Filed: Jul. 2, 2013

Related U.S. Application Data
(60) Provisional application No. 61/680,364, filed on Aug. 7, 2012.

(51) Int. Cl. H01L 23/498

(52) U.S. Cl. CPC H01L 23/49811
USPC 257/737

(57) ABSTRACT

An exemplary flip-chip package is provided, including: a package structure having a first bonding pad and a second bonding pad formed thereon, wherein the first bond pad has a feature size different from a feature size of the second bond pad; a semiconductor chip facing the package structure, having a first under bump metal (UBM) layer and a second under bump metal (UBM) layer formed thereon, wherein the first UBM layer has a feature size different from a feature size of the second UBM layer; a first conductive element disposed between the first bond pad and the first UBM layer; and a second conductive element disposed between the second bond pad and the second UBM layer.

### CROSS REFERENCE TO RELATED APPLICATIONS

This application claims the benefit of U.S. Provisional Application No. 61/680,364 filed on Aug. 7, 2012, the entirety of which is incorporated by reference herein.

### BACKGROUND OF THE INVENTION

1. Field of the Invention

The present invention relates to a semiconductor flip-chip package, and in particular, to a flip-chip package having under bump metal (UBM) layers with various feature sizes for optimizing current rating requirements.

2. Description of the Related Art

With improvement in the speed and integration of semiconductor chips, sizes of semiconductor chip elements have become finer, and the number of I/O pads over the semiconductor chip has increased.

Methods for packaging a semiconductor chip, such as a ball grid array package and a chip scale package, have recently been introduced. The semiconductor chip is packaged using diverse electric connections such as wire bonding, tape automated bonding (TAB), and flip-chip bonding.

Flip-chip bonding is the most effective type of packaging technique for high-speed, intelligent and high-density packaging, in which an electrode arranged on the semiconductor chip is directly connected to a package substrate connection terminal

### BRIEF SUMMARY OF THE INVENTION

An exemplary flip-chip package is provided, comprising: a package structure having a first bonding pad and a second bonding pad formed thereon, wherein the first bond pad has a feature size different from a feature size of the second bond pad; a semiconductor chip facing the package structure, having a first under bump metal (UBM) layer and a second under bump metal (UBM) layer formed thereon, wherein the first UBM layer has a feature size different from a feature size of the second UBM layer; a first conductive element disposed between the first bond pad and the first UBM layer; and a second conductive element disposed between the second bond pad and the second UBM layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a flip-chip package according to an embodiment of the invention;

FIG. 2 is a schematic diagram showing an enlargement view of an area 500 in FIG. 1;

FIG. 3 is a schematic bottom view of a semiconductor chip in the flip-chip package of FIG. 1;

FIG. 4 is a flip-chip package according to another embodiment of the invention;

FIG. 5 is a schematic diagram showing an enlargement view of an area 500′ in FIG. 4; and

FIG. 6 is a schematic bottom view of a semiconductor chip in the flip-chip package of FIG. 4.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

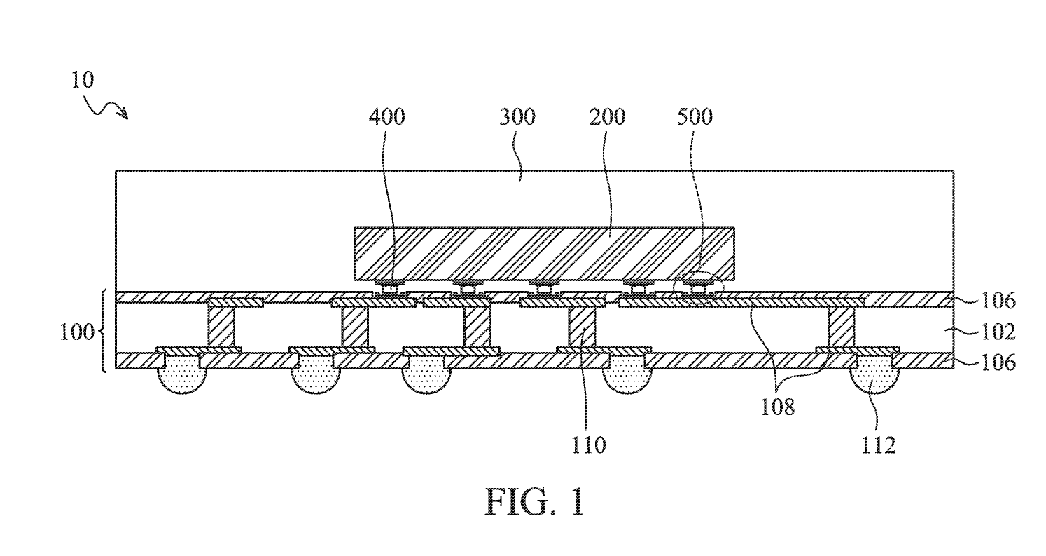

FIG. 1 shows an exemplary flip-chip package 10. The exemplary flip-chip package 10 shown in FIG. 1 is a comparative embodiment for describing a semiconductor package having current rating optimization issues found by the inventors, and does not limit the scope of the present application.

As shown in FIG. 1, the flip-chip package 10 comprises a package structure 100, a semiconductor chip 200 disposed over a portion of the package structure 100, and an encapsulant layer 300 covering the package structure 100 and the semiconductor chip 200. In addition, a plurality of conductive elements 400 are separately provided between various portions of the semiconductor chip 200 and the package structure 100 to physically and electrically connect the semiconductor chip 200 with the package structure 100, thereby forming a semiconductor flip-chip package.

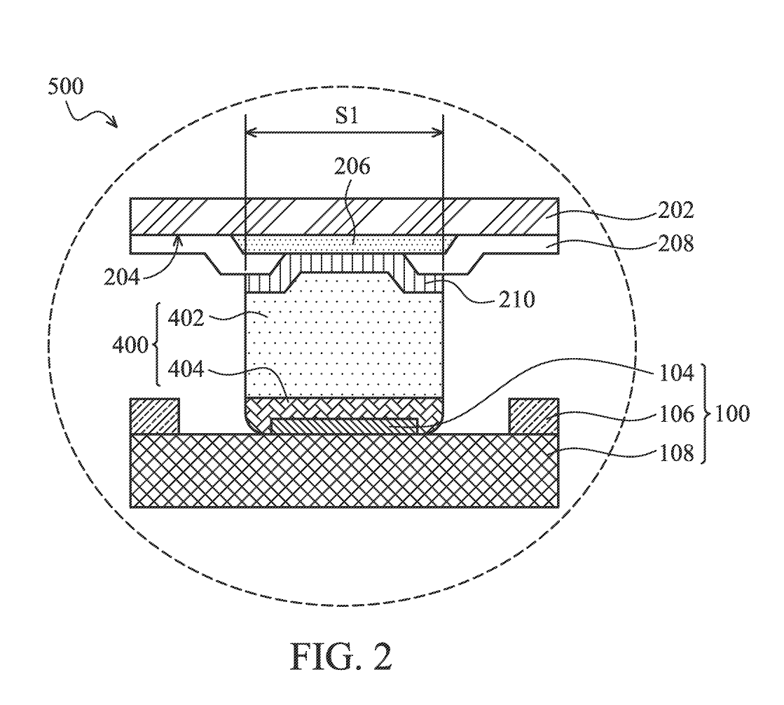

Referring to FIG. 2, a schematic diagram showing an enlargement view of an area 500 in FIG. 1 is illustrated. As shown in FIG. 2, the semiconductor chip 200 may comprise a semiconductor structure 202 having an active surface 204 facing the package structure 100, a bonding pad 206 formed over a portion of the active surface 204 of the semiconductor substrate 202, and a passivation layer 208 formed over the active surface 204 to cover portions of the bonding pad 206 and to expose a portion of the bonding pad 206. An under bump metal (UBM) layer 210 formed over the portion of the bonding pad 206 exposed by the passivation layer 208 and covering portions of the passivation layer 208 over the bonding pad 206. A feature size S1 such as a width or a diameter of the UBM layer 210 is used to define a size of the conductive element 400 formed thereon. In one embodiment, the semiconductor chip 200 may comprise a semiconductor substrate (not shown) such as a silicon substrate, active or passive electrical elements (both not shown) such as transistors, capacitors, resistors or the like formed in or over the semiconductor substrate, and an interconnect structure having conductive vias and lines and insulating dielectric layers (not shown). In another embodiment, the conductive element 400 can be, for example, a copper-containing pillar comprising a copper portion 402 made of copper or copper alloy and a solder cap portion 404 made of tin or tin alloy formed over the copper portion 402. In other embodiments, the conductive element 400 can be a solder bump made of tin or tin alloy. In one embodiment, the UBM layer 210 may comprise alloys of conductive materials such as Ti/Cu, and Ti/Cu/Cu/Ni.

As shown in FIGS. 1-2, the package structure 100 comprises an insulating substrate 102 with a plurality of bonding pads 104 formed thereover, a plurality of patterned solder mask layer 106 and a plurality of conductive traces 108 formed on opposite surfaces of the insulating substrate 102, and a plurality of conductive vias 110 (see FIG. 1) formed through various portions of the insulating substrate 102. Each of the bonding pads 104 is exposed and defined by the patterned solder mask layer 106 formed over a surface of the insulating substrate 102 facing the semiconductor chip 200. A plurality of solder bumps 112 are formed over the surface of the insulation substrate 102 not facing the semiconductor chip 200, thus electrically connecting to the conductive elements 400 through the conductive traces 108 and the conductive vias 110. In one embodiment, the insulating substrate 102 may comprise insulating material such as a glass-fiber-reinforced epoxy (FR4) or ceramic, the bonding pads 104 may comprise conductive materials such as aluminum or aluminum alloys, and the conductive traces 108 and the conductive vias 110 may comprise conductive materials such as copper or copper alloys.

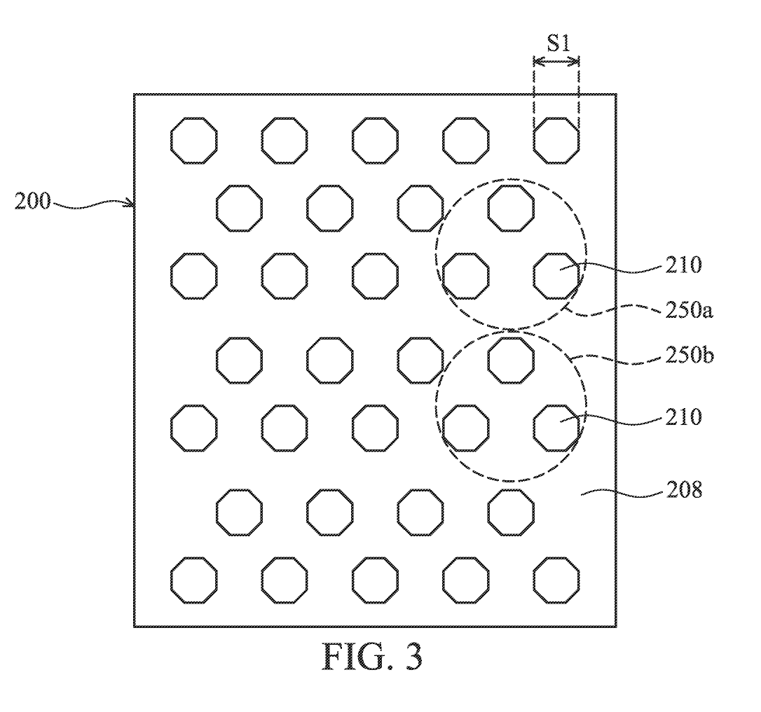

FIG. 3 is a schematic bottom view of the semiconductor chip 200 shown in FIG. 1. As shown in FIG. 3, the passivation layer 208 and the plurality of UBM layers 210 formed over the semiconductor chip 200 are illustrated. In this embodiment, the UBM layers 210 are separately formed and arranged over the semiconductor chip 200, having the same feature size S1 (e.g. the width) and the same configurations (e.g. an octagonal configuration) for forming the conductive element 400 thereon. For use in the flip-chip package 10 shown in FIG. 1, a design of a maximum sustained current of the conductive elements 400 formed between the semiconductor chip 200 and the package structure 100 is dominated by the feature size S1 of the UBM layers 210. Therefore, to meet high current signal requirements, for example, a power supply signal requirement, during an operation of the flip-chip package 10, several adjacent UBM layers 210 and the conductive elements 400 formed thereon are collectively applied for transferring a high current signal to meet the power supply signal requirements. For example, the adjacent UBM layers 210 in the areas 250a and 250b shown in FIG. 3 may be collectively applied to transfer different high current signals through the conductive element 400 (see FIGS. 1-2) formed thereon, such that numbers of the conductive elements 400 (see FIGS. 1-2) and the UBM layers 210 formed over the semiconductor chip 200 used for other functional requirements of relative lower current signals such as logic signals or digital signals are thus reduced, thereby limiting the functional design of the I/O pad of the semiconductor chip 200.

Therefore, an improved flip-chip package for optimizing current rating requirements is needed.

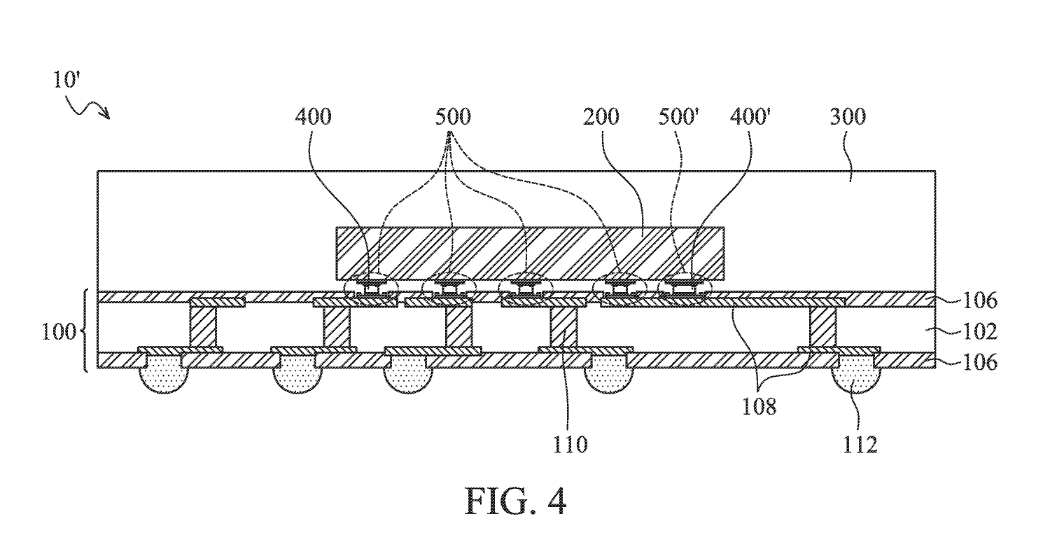

FIG. 4 shows another exemplary flip-chip package 10′ similar with the flip-chip package 10 shown in FIGS. 1-2. The exemplary flip-chip package 10′ shown in FIG. 4 is an embodiment for showing a semiconductor package allowing current rating optimization. For the purpose of simplicity, same reference numbers in FIG. 4 represent the same elements shown in FIGS. 1-2, and only differences between the flip-chip packages 10 and 10′ are discussed as follows.

As shown in FIG. 4, the flip-chip package 10′ comprises a package structure 100, a semiconductor chip 200 disposed over a portion of the package structure 100, and an encapsulant layer 300 covering the package structure 100 and the semiconductor chip 200. In addition, a plurality of conductive elements 400 and 400′ are separately provided between various portions of the semiconductor chip 200 and the package structure 100 to physically and electrically connect the semiconductor chip 200 with the package structure 100, thereby forming a semiconductor flip-chip package. The components in the areas 500 are the same as that shown in FIG. 2 and are not described here again, for simplicity.

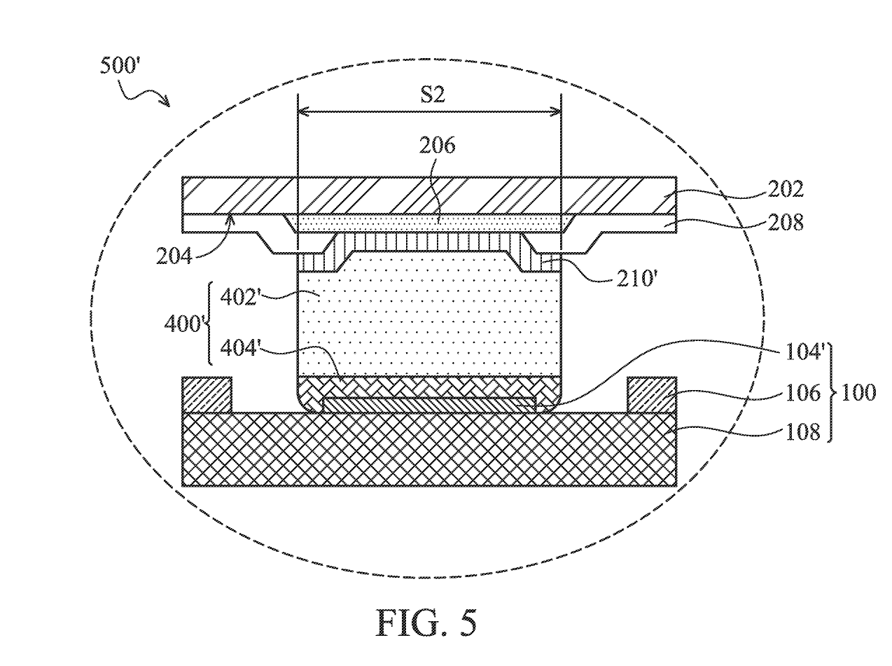

Referring to FIG. 5, a schematic diagram showing an enlargement view of an area 500′ in FIG. 4 is illustrated. As shown in FIG. 5, an under bump metal (UBM) layer 210′ is formed over a portion of the bonding pad 206 exposed by the passivation layer 208 to cover portions of the passivation layer 208 over the bonding pad 206. A feature size S2 such as a width or a diameter of the UBM layer 210′ is used to define a size of the conductive element 400′ formed thereon. At this time, the feature size S2 of the UBM layer 210′ is different from the feature size S1 of the other UBM layers 210 in the areas 500 as illustrated in FIG. 2. In one embodiment, the feature size S2 is about, for example 150-500% greater than the feature size S1. Similarly, a copper portion 402′ and a solder cap portion 404′ of the conductive element 400′ shown in FIG. 5 also have a feature size greater than that of the copper portion 402 and the solder cap portion 404 of the conductive element 400 shown in FIG. 2.

In FIGS. 4-5, the package structure 100 comprises an insulating substrate 102 a plurality of bonding pads 104 and 104′ formed thereover, a plurality of patterned solder mask layer 106 and a plurality of conductive traces 108 (See FIG. 4) formed on opposite surfaces of the insulating substrate 102, and a plurality of conductive vias 110 (see FIG. 4) formed through various portions of the insulating substrate 102. Each of the bonding pads 104 and 104′ is exposed and defined by a patterned solder mask layer 106 formed over the insulating substrate 102, and a feature size of the bonding pad 104′ is about, for example 150-500% greater than a feature size of the bonding pad 104 in the areas 500 (See FIG. 2). In one embodiment, the bonding pad 104′ may comprise the same conductive materials as that of the bonding pad 104. The other areas 500 shown in FIG. 4 may have the same components and the same enlargement view as that shown in FIG. 2.

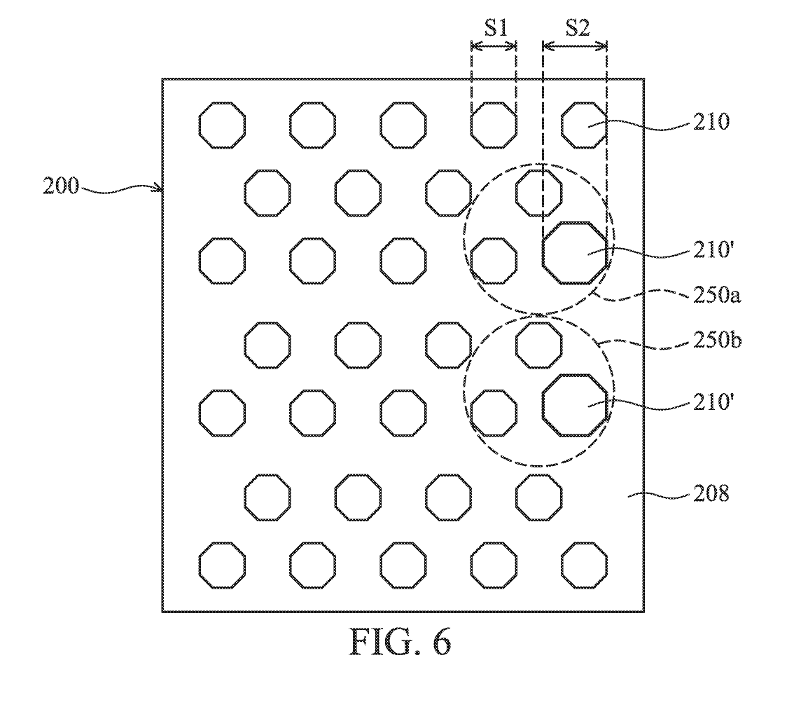

FIG. 6 is a schematic bottom view of the semiconductor chip 200 shown in FIG. 4. As shown in FIG. 6, the passivation layer 208 and the plurality of UBM layers 210 and 210′ formed over the semiconductor substrate 200 are illustrated. In this embodiment, the UBM layers 210 and 210′ are separately formed and arranged over the semiconductor chip 200. The UBM layers 210 have the same feature size S1 (e.g. the width) and the same configurations (e.g. an octagonal configuration) for forming the conductive element 400 thereon, and the UBM layers 210′ have the same feature size S2 (e.g. the width) greater than the features size S1, and the same configurations (e.g. an octagonal configuration) for forming the conductive element 400′ thereon.

In the flip-chip package 10′ shown in FIGS. 4-5, a design of a maximum sustained current of the conductive elements 400′ is enlarged by the feature size S2 of the UBM layers 210′ in the areas 250a and 250b. Therefore, since the feature size S2 is increased and greater than that of the other UBM layers 210 formed over the semiconductor chip 200, such that a high current signal, for example a power supply signal, during an operation of the flip-chip package 10′, can safely pass through the conductive element 400′ over the UBM layers 210′.

Referring to FIGS. 3 and 6, the adjacent UBM layers 210 in the area 250a and 250b shown in FIG. 3 can be redesigned and a UBM layer 210′ can be formed in each of the areas 250a and 250b shown in FIG. 6, such that high current signals can be sustained and pass through the conductive elements 402′ (see FIGS. 4-5). Therefore, additional conductive elements 402 and the UBM layers 210 can be formed over the areas 250a and 250b of the semiconductor chip 200 for other function requirements of relatively lower current signals such as logic signals or digital signals. A location of the UBM layer 210′ can be further modified according to design of the flip-chip package 10′ and can be disposed at any place over the active surface the semiconductor chip 200 and is not limited to an edge portion as illustrated in FIG. 6.

Accordingly, the flip-chip package 10′ shown in FIGS. 4-6 having under bump metal (UBM) layers with various feature sizes is good for optimizing current rating requirements. Package design of the flip-chip package 10′ can be thus balanced. In other embodiments, the UBM layers 210 and the conductive elements 402 in the areas 250a and 250b of the semiconductor chip 200 can be cancelled to save a connection area and provide better signal performances.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flip-chip package, comprising:
a package structure having a first bonding pad and a second bonding pad formed thereon, wherein the first bond pad has a feature size different from a feature size of the second bond pad;
a semiconductor chip facing the package structure, having a first under bump metal (UBM) layer and a second under bump metal (UBM) layer formed thereon, wherein the first UBM layer has a feature size different from a feature size of the second UBM layer;
a first conductive element disposed between the first bond pad and the first UBM layer; and
a second conductive element disposed between the second bond pad and the second UBM layer.

2. The flip-chip package as claimed in claim 1, wherein the first and second conductive elements comprise copper-containing pillars.

3. The flip-chip package as claimed in claim 1, wherein the first and second conductive elements comprise solder bumps.

4. The flip-chip package as claimed in claim 1, wherein the first and second UBM layers comprise alloys of Ti/Cu or Ti/Cu/Cu/Ni.

5. The flip-chip package as claimed in claim 1, furthering comprising an encapsulant layer covering the semiconductor chip and the package structure.

6. The flip-chip package as claimed in claim 1, wherein the first and second bonding pads are formed over a first surface of the package structure, and the package structure further comprises a second surface opposing to the first surface and a plurality of solder balls formed on the second surface.

7. The flip-chip package as claimed in claim 6, wherein the solder balls electrically connects to the first and second bonding pads, respectively.

8. The flip-chip package as claimed in claim 1, wherein the first and second UMB layers are formed over an active surface of the semiconductor chip.

9. The flip-chip package as claimed in claim 1, wherein the feature size of the first UBM layer is about 150-500% greater than the feature size of the second UBM layer.

10. The flip-chip package as claimed in claim 1, wherein the feature size of the first bonding pad is about 150-500% greater than the feature size of the second bonding pad.
